(19) United States
(12) Patent Application Publication
(10) Pub. No.: US 2026/0286568 A1
(43) Pub. Date: Sep. 24, 2026

(54) METHOD FOR THE CONTROLLED DEPOSITION OF AN OXIDE LAYER OF A TARGET OXIDE ON A SUBSTRATE IN A TLE SYSTEM, AND TLE SYSTEM

(71) Applicant: Max-Planck-Gesellschaft zur Förderung der Wissenschaften e.V., München (DE)

(72) Inventors: Wolfgang Braun, Bietigheim-Bissingen (DE); Jochen Mannhart, Böblingen (DE); Brendan Faeth, Stuttgart (DE); Felix Hensling, Stuttgart (DE)

(21) Appl. No.: 19/476,042

(22) PCT Filed: Apr. 17, 2023
(86) PCT No.: PCT/EP2023/059910

§ 371 Date: Oct. 16, 2025

(51) Int. Cl. C30B 25/10; C23C 16/40; C23C 16/46; C23C 16/50; C30B 29/20; C30B 29/22

(52) U.S. Cl. CPC C30B 25/105; C23C 16/403; C23C 16/404; C23C 16/46; C23C 16/50; C30B 29/20; C30B 29/22

(57) ABSTRACT

The invention relates to a method for the controlled deposition of an oxide layer (80) of an target ox-ide (82) on a substrate (70) in a thermal laser epitaxy (TLE) system (100), the target oxide (82) comprising a defined stoichiometry and being formed from one or more evaporated and/or sublimated source materials and oxygen originating from a gaseous oxidizing agent (54), the TLE system (100) further comprising a reaction chamber (10) and one or more laser sources (20) for providing laser beams (22) within the reaction chamber (10). Further, the invention relates to a TLE system (100) constructed for carrying out said method.

The invention relates to a method for the controlled deposition of an oxide layer of a target oxide on a substrate in a thermal laser epitaxy (TLE) system, the target oxide comprising a defined stoichiometry and being formed from one or more evaporated and/or sublimated source materials and oxygen originating from a gaseous oxidizing agent, the TLE system further comprising a reaction chamber and one or more laser sources for providing laser beams within the reaction chamber. Further, the invention relates to a TLE system constructed for carrying out said method.

Epitaxial oxide films may currently be produced by a variety of methods such as pulsed laser deposition (PLD), atomic layer deposition (ALD), chemical vapor deposition (CVD), sputtering and molecular beam epitaxy (MBE). Whereas all of these methods allow the deposition of oxide films with rather good stoichiometry, by far the best stoichiometry is achieved by growing epitaxial oxide films by MBE in the adsorption-controlled growth mode.

Adsorption-limited growth works best in an ultrahigh purity environment, which usually means ultrahigh vacuum, or a residual gas atmosphere with extreme gas purity. This implies that non-thermal flux generation such as by sputtering or ablation, will not work due to the liberation of impurities from the chamber walls or source material holders, and due to changes to the growing crystal surface by charged and/or highly energetic source material atoms or molecules. Thermal flux generation by evaporation (from a molten material) or sublimation (from a solid material) is therefore required.

Oxides are difficult to grow in the adsorption-controlled growth mode as they mostly require high substrate temperatures due to their high binding energies, and the presence of oxygen or an oxidizing agent to achieve the desired oxidation state. In many cases, the strong oxidizing conditions necessary for stoichiometric growth are incompatible with the Joule heater technology used in MBE, since conductors such as metals oxidize and fail in the presence of oxygen at high temperatures. Successful examples of oxides grown by MBE in the adsorption-controlled growth mode are therefore restricted to low (less than about 1000° C.) substrate temperatures and low (less than 10-5 hPa) oxygen or ozone pressures. The required high substrate temperature also weakens the oxidation potential, which means that correspondingly even higher oxygen or oxidant pressures are required for high quality crystal growth, a condition which is even harder to meet with MBE.

In view of the above, it is an object of the present invention to provide an improved method for the controlled deposition of an oxide layer, and an improved thermal laser evaporation system which do not have the aforementioned drawbacks of the state of the art. In particular, it is an object of the present invention to provide an improved method for the controlled deposition of an oxide layer, and an improved thermal laser evaporation system which provide the possibility of a deposition of an oxide layer consisting of one or more elemental constituents and oxygen, wherein both the stoichiometry of the deposited oxide and also the actual deposition of the oxide layer can actively be controlled.

This object is satisfied by the respective independent patent claims. In particular, this object is satisfied by a method for the controlled deposition of an oxide layer according to independent claim 1, and by a TLE system according to independent claim 31. The dependent claims describe preferred embodiments of the invention. Details and advantages described with respect to the method according to the first aspect of the invention also refer to a TLE system according to the second aspect of the invention, and vice versa, if of technical sense.

According to a first aspect of the invention the object is satisfied by a method for the controlled deposition of an oxide layer of a target oxide on a substrate in a thermal laser epitaxy (TLE) system, the target oxide comprising a defined stoichiometry and being formed from one or more evaporated and/or sublimated source materials and oxygen originating from a gaseous oxidizing agent, the TLE system further comprising a reaction chamber and one or more laser sources for providing laser beams within the reaction chamber. The method according to the present invention is characterized by the steps of:
a) providing the substrate and a first deposition source in the reaction chamber, wherein the first deposition source contains an elemental material as first source material,
b) filling the reaction chamber with a reaction gas comprising one or more oxidizing agents provided by a gas system of the TLE system,
c) evaporating and/or sublimating the first source material by impinging a laser beam of the TLE system on the first source material with an intensity below a plasma generation threshold of the first source material, for providing a flux of evaporated and/or sublimated first source material and/or of a first binary oxide formed from the first source material with the oxidizing agent, wherein the flux is directed towards the substrate,
d) heating the substrate to a deposition temperature by a laser beam of the TLE system, wherein the deposition temperature of the substrate is equal or higher to a desorption temperature such that the first deposition source and/or the first binary oxide desorb at least partly from the substrate,
e) forming the target oxide by combining the one or more evaporated and/or sublimated source materials and oxygen originating from the one or more oxidizing agents and depositing the target oxide as oxide layer onto the substrate,
   wherein the formation of the target oxide and the deposition of the oxide layer on the substrate is controlled by controlling the filling of the reaction chamber with the reaction gas in step b) and/or by controlling the rate of the evaporated and/or sublimated first source material at the substrate in step c) and/or by controlling the deposition temperature in step d).

The method according to the present invention is intended to be carried out in and with a thermal laser epitaxy (TLE) system. TLE systems are the best choice for providing a controlled deposition of a target oxide comprising a desired and hence defined stoichiometry.

Said TLE system at least comprises a reaction chamber for providing a reaction volume sealable with respect to the ambient environment. In said reaction chamber, one or more deposition sources and a substrate to be coated are arranged, held in place by arrangement means.

Further, the TLE system comprises a gas system for providing a selectable atmosphere within the reaction chamber. The gas system is at least capable of providing a reaction gas into the reaction chamber, wherein the reaction gas contains one or more gaseous oxidizing agents such as for instance molecular oxygen or ozone. However, the gas system can also be constructed for providing other reaction gases, such as for instance molecular nitrogen, and/or for evacuating the reaction chamber to pressures, in particular up to ultra-high vacuum with pressures as low as 10⁻¹² hPa or even lower.

In addition, the TLE system comprises one or more laser sources and coupling means accordingly provided on and/or at the reaction chamber for providing laser beams within the reaction chamber. The laser beams are used for evaporation and/or sublimation of the one or more source materials and for the heating of a substrate. Thereby any additional heating of the one or more deposition sources and of the substrate by electric heating means, as for instance used in MBE, are not needed. Limitations caused by said heating means for the used reaction gas, for instance concerning the provided oxidizing agent and/or its pressure, can be avoided.

In summary, by using a TLE system for carrying out the method according to the present invention, a high purity environment for the deposition of the oxide layer can be provided. Every element of the TLE system, in particular the evaporation and/or sublimation of the one or more source materials, the heating of the substrate, and also the gas system for providing the reaction gas, can be individually and actively controlled for ensuring the deposition of the target oxide comprising the desired and hence defined stoichiometry.

In the first step a) of the method according to the present invention, the substrate and a first deposition source are arranged and hence provided in the reaction chamber. This can be carried out when the reaction chamber is still open with respect to the ambient environment, but can also be made possible by means of correspondingly available airlocks when the reaction chamber is already closed and sealed. Within the reaction chamber, arrangement means are present for the respective arrangement of both the substrate and the one or more deposition source, respectively. Said arrangement means can be provided for spatially fixing the substrate and/or the one or more deposition source only. Alternatively, or additionally, these arrangement means can also be designed to provide movements of the substrate and/or of the one or more deposition source, for example to move the substrate in and out of a deposition position, and/or to exchange the deposition source to be used. In summary, after execution of step a), the first deposition source and the substrate are arranged within the reaction chamber.

In particular, the first deposition source contains an elemental material as source material. In other words, the source material is pure, which means it consists to a very large degree of one element from the periodic table of elements only, except oxygen itself, and the elemental material, which is accordingly selected for forming the non-oxygen constituent of the target oxide, is provided without any precursor molecules. Nevertheless, it is possible that the surface of the source material, which faces the environment and especially, after execution of step b) of the method according to the present invention, the reaction gas comprising one or more oxidizing agents, is oxidized and hence an uppermost layer of the deposition source is formed by an oxide of the elemental material forming the bulk of the deposition source.

In the next step b) of the method according to the present invention, the gas system of the TLE system is used for accordingly preparing the atmosphere within the reaction chamber for the deposition of the oxide layer onto the substrate. In particular, the reaction gas comprising one or more oxidizing agents is filled into the reaction chamber. An oxidizing agent in the sense of the present invention is a gaseous substance which can be used as source for the required oxygen atoms during the formation of the target oxide. Preferably, the reaction gas consists of the one or more oxidizing agents.

Before said filling of the reaction chamber with the reaction gas, the reaction chamber preferably is evacuated by the gas system. By that the purity of a reaction atmosphere consisting only of the reaction gas can be provided or at least drastically improved. After execution of step b), by many orders of magnitude in concentration, only the reaction gas comprising, preferably consisting of, the one or more oxidizing agents is present as atmosphere within the reaction chamber. If air locks are used in step a) for arranging the substrate and/or the first deposition source in the reaction chamber, step b) can be carried out also before and/or during the execution of step a).

After preparing the reaction chamber in steps a), b), in the next step c) the actual evaporation and/or sublimation of the first source material, namely the elemental material, takes place. In particular, as the method according to the present invention is carried out by a TLE system, a laser beam provided by a respective laser source of the TLE system is used for the evaporation and/or sublimation. The laser beam is coupled into the reaction chamber and directed onto the surface of the source material.

The intensity of the laser beam is selected below a plasma threshold of the first source material. Hence, an exclusively thermal evaporation and/or sublimation of the first source material is provided, in particular without explosive ablation or the formation of a plasma as present in PLD and/or sputtering processes. Evaporated and/or sublimated first source material can thereby be provided. If the surface of the deposition source is oxidized, as described above, also evaporation and/or sublimation of said oxide of the source material is possible. In addition, the evaporated and/or sublimated first source material can also react with the one or more oxidizing agents of the reaction gas, forming a first binary oxide of the first source material.

A binary oxide in the sense of the invention is an oxide comprising two types of constituents, namely an elemental material and oxygen, the actual stoichiometry of said binary oxide is not fixed. For instance, with titanium as metal, the oxides TiO, TiO₂, and Ti₂O₃ are all binary oxides in the sense of the present invention. The same applies accordingly to ternary or multernary oxides, i.e. oxides with two and three or more elemental non-oxygen constituents.

In summary, in step c) a flux of the evaporated and/or sublimated first source material and/or of the first binary oxide is provided. Said flux is provided towards the substrate to be coated, for instance by accordingly arranging the first deposition source and the substrate within the reaction chamber in step a) of the method according to the present invention.

In step d) of the method according to the present invention, the substrate is prepared for the deposition of the target oxide for forming the intended oxide layer. For this, the substrate is heated by a laser beam provided by an accordingly provided laser source of the TLE system. Likewise, to the laser beam used for evaporating and/or sublimating the first source material, also the laser beam for the heating of the substrate is coupled into the reaction chamber and directed onto the substrate.

In particular, the heating of the substrate is provided such that the substrate comprises a defined and selected deposition temperature. Said deposition temperature is selected to be equal to or higher than a desorption temperature such that the first deposition source and/or the first binary oxide desorbs at least partly from the substrate. Thereby the respective deposition temperature depends on the properties of the substrate itself, but also on the used first source material and/or the already formed first binary oxide.

Setting the deposition temperature equal or higher than the respective desorption temperature provides the effect that a dependency of a deposition rate of the target oxide, and hence a growth rate of the oxide layer, from the flux density of the evaporated and/or sublimated first source material is drastically reduced, preferably eliminated. On the other hand, this loss of dependency allows controlling the deposition rate by other properties, namely by the selection of a suitable deposition temperature and especially by the amount of oxygen available for the formation of the target oxide. This is especially based on the finding that the first source material in its pure form, namely the elemental material, or metastable oxides of this material, are in most of the cases more volatile than desired oxides of the respective material, and that a specific binary oxide of the first source material also provides a specific desorption temperature which can be considered when selecting the deposition temperature at which the substrate is to be heated. In summary, these effects combined provide the possibility to grow also a binary oxide as target oxide in an adsorption-controlled way.

Finally, in step e) of the method according to the present invention, the target oxide is formed and deposited onto the substrate for forming the oxide layer. The target oxide comprises as constituents the first source material and oxygen. The stoichiometry of the target oxide is defined and selected. Said forming of the target oxide can be provided directly on the substrate. However, if the target oxide is a first binary oxide already formed in advance of the deposition on the substrate, this is also considered as enclosed in forming the target oxide in of step e) in the sense of the present invention. According to the present invention, both said formation of the target oxide, and the deposition of the oxide layer onto the substrate, respectively, are controlled.

In particular, controlling the formation of the target oxide and/or the deposition of the oxide layer can be provided by controlling the filling of the reaction chamber with the reaction gas. As mentioned above, the deposition temperature of the substrate can be chosen such that the first source material in its pure form, or in the form of a less stable oxide, desorbs from the substrate, and in contrast to that the target oxide is absorbed at the surface of the substrate. Hence by controlling the filling in step b) the amount of available oxygen can be controlled and hence the formation rate of the less stable or the target oxide can be actively adjusted. In other words, controlling the filling of the reaction chamber with reaction gas provides a way of growing the oxide layer in an adsorption-controlled way.

Additionally, or alternatively, also the rate of the evaporated and/or sublimated first source material at the substrate in step c) can be used for controlling the formation of the target oxide and/or the deposition of the oxide layer. In particular, the rate of evaporated and/or sublimated first source material defines the maximal rate at which the target oxide can be formed, and hence the maximum growth rate of the oxide layer on the substrate. Lowering the rate of the evaporated and/or sublimated first source material, for instance by lowering the intensity of the laser beam used for the evaporation and/or sublimation, also the maximum value of the formation rate of the target oxide gets lower.

Again additionally, or alternatively, also the deposition temperature at which the substrate is set in step d) has an influence on the formation of the target oxide and the deposition of the oxide layer on the substrate. In particular, as mentioned above, different oxides of the first source material in most of the cases comprise different desorption temperatures. Hence, by controlling, and thereby accordingly adjusting, the deposition temperature, the selection of the target oxide can be actively altered. Also, the fraction of desorption, in other words the fraction of impinging material on the substrate which again subsequently desorbs, depends in most of the cases on the temperature of the substrate. Also, this property can be used for controlling the formation of the target oxide and the deposition of the oxide layer on the substrate. Finally, and most important, a deposition predominantly only takes place, if the formed compound, namely the target oxide, possesses the required suitable thermodynamic properties, which dominantly depend on the substrate temperature. Thereby the deposited compound, namely the target oxide, can be actively selected and hence the quality of the deposited layer, in particular concerning high purity and low defect density, can be maximized.

In summary, the method according to the present invention provides the possibility of a deposition of an oxide layer consisting of an elemental material constituent and oxygen with controlled stoichiometry and likewise controlled growth rate. By implementing the method according to the present invention, said deposition can be provided in an adsorption-controlled way. This exploits in particular, that the deposition only takes place if the formed compound, namely the target oxide, possess the required suitable thermodynamic properties, which dominantly depend on the substrate temperature. Hence, in particular controlling the substrate temperature allows producing said oxide layer consisting of the target oxide in exceedingly high quality, even if binary oxides are chosen for target oxides. This is due to the self-adjusting stoichiometry of the target oxide under adsorption-controlled conditions.

Preferably, at least steps c), d), and e) of the method according to the present invention are carried out simultaneously.

In a first embodiment, the method according to the present invention can be characterized in that in step d) the deposition temperature is selected such that more than 40%, in particular more than 70%, preferably more than 99.99%, of the incoming flux of the first source material desorbs from the substrate, and that in step e) the adsorbed part of the first source material combined with oxygen originating from the one or more oxidizing agents and/or the first binary oxide form the target oxide for the deposition of the oxide layer. In other words, the first source material not bound in the stable stoichiometric target oxide desorbs from the substrate, preferably completely or at least essentially completely. Only the target oxide, also the first binary oxide if its stoichiometry complies to the target oxide, is deposited onto the substrate. As the formation of the target oxide depends on the availability of oxygen, which again is controlled in step b) of the method according to the present invention by the filling of the reaction chamber with reaction gas, an adsorption-controlled way for depositing a binary oxide on a substrate, and hence in particular the advantage of the exceedingly high structural and stoichiometric quality of an oxide layer deposited in this way, can be provided more easily.

According to an alternative embodiment, the method according to the present invention can comprise that in step a) one or more second deposition sources are provided in the reaction chamber, wherein each second deposition source contains an elemental material as second source material, further that step c) includes evaporating and/or sublimating one or more second source materials by impinging a laser beam of the TLE system on the one or more second source materials with an intensity below a plasma generation threshold of the respective second source material, for providing a flux of evaporated and/or sublimated one or more second source materials and/or of one or more second binary oxides formed from one of the one or more second source materials with the oxidizing agent directed towards the substrate, wherein in step e) the first deposition source and/or the first binary oxide combined with the one or more second deposition sources and/or the one or more second binary oxides, if necessary additionally combined with oxygen originating from the one or more oxidizing agents, form the target oxide for the deposition of the oxide layer, and that in step d) the deposition temperature of the substrate is equal or higher to a temperature such that the first deposition source and/or the first binary oxide desorb if they are not used for forming the target oxide.

In contrast to the embodiment described above, one or more additional second deposition sources are arranged in the reaction chamber in step a) of the method according to the present invention. Subsequently, the one or more second source materials of said one or more second deposition sources, again elemental non-oxygen materials, are evaporated and/or sublimated by accordingly provided laser beams of the TLE system. All features and advantages described above concerning the first deposition source and the first source material also apply for each of the one or more second deposition sources and the respective one or more second source materials.

By providing one or more second source materials, respectively by providing the fluxes of the evaporated and/or sublimated one or more source materials and/or their respective binary oxides, the formation of a ternary, if a single second deposition source is present, or of a multernary oxide, if two or more second deposition sources are present, can be provided as target oxide. Again, the target oxide comprises as constituents the first source material, the one or more second source materials, and oxygen, wherein the stoichiometry of the target oxide is defined and selected in a self-adjusting way by the thermodynamic properties of the target oxide, the substrate temperature and the flux densities of the source materials and the oxidizing agents.

In particular, in the present embodiment of the method according to the present invention, the heating of the substrate in step d) is controlled such that the resulting deposition temperature of the substrate is high enough that both the first source material and the first binary oxide, respectively, desorb. Only if the first source material and/or the first binary oxide, depending on which of them is present at the substrate, combines with an element of the one or more second source materials and/or the one or more second binary oxides to form the target oxide with the selected and defined stoichiometry, in other words only if the respective ternary or multernary oxide defined as target oxide is formed, a deposition of the reaction product at the substrate takes place.

In other words, the deposition of the target oxide is adsorption-controlled. Hence, by implementing this embodiment of the method according to the present invention, all advantages described above concerning a deposition in an adsorption-controlled way, in particular the exceedingly high structural and stoichiometric quality of the deposited oxide layer, can also be provided for oxide layers formed from ternary and multernary oxides. In particular the first source material and/or the first binary oxide represents the volatile part of the compound to be formed, namely the target oxide, which is provided in excess. Further, the one or more second source materials and/or the respective second binary oxides form the rate limiting, non-volatile part of the compound. Hence, the flux of the one or more evaporated and/or sublimated second source materials and/or one or more second binary oxides define the forming rate of the target oxide and thereby the growth rate of the oxide layer. In summary, providing the oxide layer by depositing the target oxide in exceedingly high quality can also be provided also for ternary or multernary oxides.

Further, the method according to the present invention can be enhanced by that the deposition temperature in step d) is selected high enough that the amount of first deposition source and/or first binary oxide nevertheless deposited onto the substrate is less than 1 in 10⁴, in particular less than 1 in 10⁷, preferably less than 10¹⁰, compared to elements of the target oxide. As described above, the oxide layer can be produced in exceedingly high quality. Further, the first source material and the first binary oxide desorb from the substrate at the deposition temperature at which the substrate is provided. However, as a deposition is a chemical reaction, there can still be isolated cases of deposition of the first source material and the first binary oxide on the substrate. On the other hand, the probability of said undesired depositions of the first source material and/or the first binary oxide gets lower with rising temperature of the substrate. Hence, by accordingly selecting the deposition temperature a defect density, namely the amount of units of the first source material and/or the first binary oxide compared to the amount of units of the target oxide, of less than 1 in 10⁴, in particular less than 1 in 10⁷, preferably less than 10¹⁰, can be achieved.

The same applies to the opposite case of a too high substrate temperature, such that the first source material is incorporated in slight deficiency, such that the target oxide contains fewer units of the first source material and/or the first binary oxide compared to the amount of units of the target oxide, of less than 1 in 10⁴, in particular less than 1 in 10⁷, preferably less than 10¹⁰.

In addition, the method can also be enhanced by that in step c) the one or more evaporated and/or sublimated second source materials and/or the one or more second binary oxide is provided with an intermittent and/or constant and/or variable flux by accordingly controlling the laser beam used for evaporating and/or sublimating the one or more second source materials. As mentioned above, in the adsorption-controlled way the one or more second source materials and, if applicable, the one or more second binary oxides are the part of the compound limiting the formation of the target oxide and hence the grow of the oxide layer. Hence by altering the flux of these components, also the formation rate of the target oxide and accordingly the growth rate of the oxide layer can be actively altered and controlled.

According to another enhanced embodiment of the method according to the present invention, the target oxide formed in step e) comprises a perovskite structure and/or perovskite-related structure and/or Ruddlesden-Popper structure. Perovskite and perovskite-related compounds, especially Ruddlesden-Popper structures, are of scientific and industrial interest as strongly correlated electron systems, as candidate materials for odd parity superconductivity, and as highly efficient catalysis agents, among other things. For instance, perovskite oxides and oxides with Ruddlesden-Popper layer stacking can possess interesting properties and/or applications such as colossal magnetoresistance, superconductivity, ferroelectricity, catalytic activity, white light emitting diodes, scintillators, fuel cell, and solar cells. All these structures are ternary oxides. Hence, by using the method according to the present invention oxide layers from target oxides comprising a perovskite structure and/or perovskite-related structure and/or Ruddlesden-Popper structure can be produced with exceedingly high quality, enhancing all of the above-mentioned properties and advantages of these structures.

In addition, the method according to the present invention can be characterized in that in step d) the deposition temperature is selected such that the first source material and/or the first binary oxide and/or the one or more second source materials and/or the one or more second binary oxides are enabled to migrate along a surface of the substrate. In other words, the deposition temperature is selected such that all constituents of the target oxide can move to find an energetically favorable location at the surface of the substrate, and hence to find their designated, ideal place within the periodic crystal lattice. A lattice defect density of the target oxide and accordingly of the oxide layer can thereby be lowered even further.

Further, the method according to the present invention can comprise that in step d) the deposition temperature is provided between 250° K and 4500° K. In the method according to the present invention, a wide variety of elemental materials, in particular elemental metals, more favorably all metals providable as a solid deposition source, can be used as first source materials. By providing the deposition temperature between 250° K and 4500° K, the substrate can be heated to a temperature suitable for all of these possible first deposition sources.

The TLE system, especially the respective laser source and the laser beam provided by said laser source, is preferably capable to heat the substrate to any temperature in this range, namely to a temperature as low as 250° K and likewise to a temperature as high as 4500° K. Thereby the same TLE system can be used for producing an unprecedentedly wide variety of oxide layers with exceedingly high quality.

In addition, the method according to the present invention can also be characterized in that in step d) the deposition temperature is selected with respect to the first binary oxide. In comparison to the first source material, the first binary oxide comprises a different desorption temperature due to its chemical properties changed by the presence of the one or more oxygen atoms. Hence, by selecting the deposition temperature with respect to the first binary oxide, the selected deposition temperature is in all cases high enough to ensure a desorption also of the first deposition source.

According to an enhanced embodiment, the method according to the present invention can comprise that the deposition temperature is selected with respect to the first binary oxide equal or higher as listed below:

| | | | | | | | | |
|---|---|---|---|---|---|---|---|---|
| Li₂O | 1075° | K | Al₂O₃ | 1650° | K | BeO | 1625° | K |
| Na₂O | 800° | K | Sc₂O₃ | 1750° | K | B₂O₃ | 1000° | K |
| K₂O | 680° | K | TiO₂ | 1750° | K | MgO | 1300° | K |
| CaO | 1450° | K | V₂O₅ | 780° | K | SiO₂ | 1350° | K |
| SrO | 1575° | K | Cr₂O₃ | 1350° | K | CuO | 950° | K |
| Y₂O₂ | 1750° | K | MnO | 1300° | K | ZnO | 900° | K |
| Ag₂O | 850° | K | FeO | 1300° | K | GeO | 1050° | K |
| BaO | 1100° | K | CoO | 1250° | K | SeO₂ | 300° | K |
| La₂O₂ | 1650° | K | NiO | 1200° | K | CdO | 750° | K |
| Ce₂O₃ | 1700° | K | Ga₂O₃ | 1275° | K | TeO₂ | 700° | K |
| Pr₂O₃ | 1700° | K | ZrO₂ | 1750° | K | CsO₂ | 500° | K |
| Nd₂O₃ | 1700° | K | MoO₃ | 750° | K | Re₂O₇ | 300° | K |
| Sm₂O₃ | 1750° | K | RuO₂ | 950° | K | PtO | 1100° | K |
| Eu₂O₃ | 1600° | K | RhO | 1100° | K | Au₂O₃ | 700° | K |
| Gd₂O₃ | 1750° | K | PdO | 900° | K | HgO | 300° | K |
| Tb₂O₃ | 1850° | K | In₂O₃ | 1100° | K | Tl₂O | 700° | K |
| Dy₂O₃ | 1900° | K | SnO₂ | 1000° | K | ThO₂ | 1750° | K |
| Ho₂O₃ | 1850° | K | SbO₂ | 750° | K | UO₃ | 500° | K |
| Er₂O₃ | 1775° | K | Lu₂O₃ | 1950° | K | NpO₂ | 2250° | K |
| Tm₂O₃ | 2000° | K | PbO | 800° | K | PuO₂ | 1500° | K |
| Yb₂O₃ | 1750° | K | Bi₂O₃ | 850° | K | Am₂O₃ | 1875° | K |

The temperature values listed in the table above are the calculated desorption temperatures of the respective binary oxides in vacuum. It should be noted that with reaction gas, and hence with one or more one oxidizing agents, present in the reaction chamber, the actual deposition temperature can differ from the listed temperature. For instance, the suitable deposition temperature for Al₂O₃ as first binary oxide drops from 1650° K to 1070° K, if molecular oxygen with a pressure of 0.001 hPa is present as reaction gas in the reaction chamber.

Further, the method according to the present invention can comprise that in step c), in particular also in step d), a continuous laser beam or a laser beam with a pulse intensity below the plasma generation threshold, is used. By using a continuous laser beam, a likewise continuous heating of the respective source material, if applicable also of the substrate, can be provided. This also applies to pulsed lasers when operated for TLE purposes such that the plasma threshold for vaporizing the source material is not reached. In particular, the respective pulse width and repetition rates of the laser beam can be preferably selected such that no significant cooling of the heated entity occurs during the pulses of the laser beam, and therefore the laser heating is quasi-continuous. Suitable pulse length can be selected equal to or larger than 1 μs, in particular larger than 1 ms, preferably larger than 1 s, wherein suitable repetition rates can be selected in the range of 10-100 kHz.

In both cases, the laser beam is continuously or at least substantially continuously incident on the respective source material, if applicable also on the substrate. The respective laser beam is thus particularly not operated in a pulsed manner, that is with high laser energies and/or lengths of the laser pulses in the nanosecond range. A particularly constant and controllable or adjustable energy transfer of the laser beam into the respective source material, if applicable also into the substrate, can be provided in this way. A constant and/or controllable and adjustable temperature of the respective source material and thus a resulting evaporation rate and/or sublimation rate can be made possible in this way. If applicable, also a constant and/or controllable and adjustable temperature of the substrate can thereby be provided.

According to a further embodiment of the method according to the present invention, in step b) a pressure and/or a composition of the reaction gas is varied by accordingly controlling the gas system of the TLE system for actively changing the stoichiometry of the formed target oxide without changing the constituents. By changing the properties of the reaction gas, for instance its pressure and/or its relative or absolute composition of oxidizing agents, the abundance of available oxygen atoms for forming the target oxide can be actively changed. Hence, it can be actively selected, which of several possible stoichiometries of the target oxide is formed, or at least said selection can be supported. For instance, in the case of a Sr as first source material and Ru as second source material, molecular oxygen (O₂) as reaction gas at a pressure at the substrate surface between 10⁻⁴ and 10⁻³ hPa favors the formation of Sr₂RuO₄ as target oxide, whereas a pressure of the same reaction gas between 5×10⁻³ and 2×10⁻² hPa favors a target oxide with SrRuO₃ as stoichiometry.

Alternatively, or additionally, the method according to the present invention can also comprise that in step c) the provided flux of evaporated and/or sublimated first source material and/or of a first binary oxide is varied by accordingly controlling the laser beam of the TLE system used in step c) for actively changing the stoichiometry of the formed target oxide without changing the constituents. As mentioned above, in most of the cases the first source material and/or the first binary oxide is present in excess at the substrate. However, by controlling the extent of the abundance of the first source material and/or the first binary oxide, also an influence on the target oxide to be formed can be provided.

Again alternatively, or additionally, the method according to the present invention can be enhanced by that in step d) the deposition temperature of the substrate is varied by accordingly controlling the laser beam of the TLE system for actively changing the stoichiometry of the formed target oxide without changing the constituents. As mentioned above, the temperature of the substrate defines which elements or compounds are desorbed from the surface of the substrate. Hence, by accordingly selecting the deposition temperature, automatically a selection of the target oxide to be deposited onto the substrate can be provided.

In the example with Sr and Ru mentioned above with respect to the variation of the reaction gas, the selection of Sr₂RuO₄ as target oxide can be aided by setting the desorption temperature in the range of 730° K and 1030° K, whereas a deposition temperature between 330° K and 730° K favors a target oxide with SrRuO₃ as stoichiometry.

According to another enhanced embodiment, the method according to the present invention can comprise that the variation of the reaction gas and/or the variation of the provided flux of evaporated and/or sublimated first source material and/or of a first binary oxide and/or the variation of the deposition temperature are provided before and/or during and/or after an iteration of step c). In step c) the first source material, and if present also the one or more second source materials, are evaporated and/or sublimated. Hence, by providing the respective variation before and/or after an iteration of step c), for the upcoming iteration of step c) a different target oxide can be selected. A sharp transition in the oxide layer from one target oxide to the other can thereby be provided. On the other hand, by providing the respective variations during the execution of step c), the transition from one target oxide to the next target oxide can be provided more smoothly.

For the above-mentioned sharp transition in the oxide layer, another advantage of the method according to the present invention emerges. As providing the respective source material is based on the evaporation and/or sublimation of the respective source material, a continuous heating of the respective source material is required for continuously providing the respective evaporated and/or sublimated source material. Without said heating, the source material immediately cools down due to radiative cooling, and the evaporation and/or sublimation stops. Hence, by starting and stopping the respective laser beam, for instance by implementing shutters in the beam line of the respective laser beam, a defined deposition interval can be defined, which in turn enables the provision of controlling a thickness of the deposited oxide layer, and additionally allows sharp transitions between different oxide layers.

Further, the method can be enhanced by that the oxide layer deposited in step e) comprises two or more subsequent sub-layers formed by target oxides with the same constituents but different stoichiometry, preferably different perovskite structures and/or perovskite-related structures and/or Ruddlesden-Popper structures. This can be provided in particular by the variations of the reaction gas and/or the flux of the first source material and/or of the flux of the first binary oxide and/or of the deposition temperature mentioned above. Oxide layers with a vast variety of properties can thereby be provided. For instance, the above-mentioned example of target oxides with Sr, Ru, and O as constituents comprise in fact Ruddlesden-Popper structures. Additionally, to the already mentioned examples of Sr₂RuO₄ and SrRuO₃, also Sr₂RuO₄, Sr₃Ru₂O₇ and Sr₄Ru₃O₁₀ are possible target oxides for the different sub-layers of the oxide layer.

According to another embodiment of the method according to the present invention, the first source material and/or the one or more second source material is an elemental metal. Metals are an extreme diversive group of elements, wherein oxides of metals provide extremely different properties, for instance with respect to electrical or thermal conductivity, or physical properties like hardness and toughness. By executing the method according to the present invention, a wide variety of binary oxides, ternary oxides or even multernary oxides based on metals as non-oxygen constituents can thereby be provided as possible target oxides for the produced oxide layer.

In addition, the method according to the present invention can also be characterized in that the first source material and/or the one or more second source material is selected from a group of materials comprising the members of: Li, Na, K, Ca, Sr, Y, Ag, Ba, La, Ce, Pr, Nd, Sm, Eu, Gd, Tb, Dy, Ho, Er, Tm, Yb, Lu, Pb, Bi, Al, Sc, Ti, V, Cr, Mn, Fe, Co, Ni, Ga, Zr, Mo, Ru, Rh, Pd, In, Sn, Sb, Be, B, Mg, Si, Cu, Zn, Ge, Se, Cd, Te, Cs, Re, Pt, Au, Hg, Tl, Th, U, Np, Pu, Am, Tc, Os, Rb, As. A wide variety of binary oxides, ternary oxides or even multernary oxides can thereby be provided as possible target oxides for the oxide layer produced by executing the method according to the present invention.

The method according to the present invention can also comprise that step b) is carried out continuously during the execution of step c) and/or step d) and/or step e). In step b), the reaction chamber is filled with the reaction gas, the reaction gas comprising, preferably consisting of, one or more oxidizing agents. Carrying out step b) continuously during the execution of step c) and/or step d) and/or step e) provides that also during evaporation and/or sublimation of the first source material and, if applicable, of the one or more second source materials, and/or during heating the substrate, and/or during formation of the target oxide and deposition of the oxide layer, simultaneously the reaction chamber is filled with reaction gas. A consistently high purity of the atmosphere inside the reaction chamber during the execution of the method according to the present invention, preferably during the whole deposition process in steps c), d), and e), can thereby be provided.

Further, the method according to the present invention can be characterized in that in step b) the filling of the reaction chamber includes providing a directed flow of reaction gas towards the substrate. The target oxide is deposited onto the substrate and thereby forms the oxide layer at the substrate. By providing a directed flow of reaction gas, and hence a directed flow of the one or more oxidizing agents, an increased flux density of oxygen needed for forming the target oxide at the substrate can be ensured. In particular in an adsorption-controlled deposition process, a lack of oxygen can be avoided

The directed flow of reaction gas at the same time reduces the non-directional background pressure of reaction gas. This reduces the scattering of source materials on their way from the source to the substrate, allowing a relative increase of reaction gas flux density at the substrate surface with reduced scattering, thereby allowing higher growth rates or stronger oxidation of the target oxide than what is possible with a homogeneous distribution of background gas.

In addition, the method according to the present invention can be enhanced by that the reaction gas consists of a single oxidizing agent. In other words, after step b) the whole reaction chamber is filled with this single oxidizing agent only. A purity of the reaction atmosphere present in the reaction chamber can thereby be provided, which contributes to enhancing the exceedingly high quality of the provided oxide layer even further.

According to another embodiment of the method according to the present invention, the one or more oxidizing agents are selected from the group of members consisting of molecular oxygen (O₂), ozone (O₃), plasma-activated oxygen (O₂*), ionized oxygen (O⁻), atomic oxygen (O), and combinations of the foregoing. This list is not closed, and also other oxidizing agents providing the oxygen needed for forming the target oxide can be used. In particular the oxidizing agents listed above consist of oxygen atoms. A contamination with other elements caused by the oxidizing agent ca thereby be avoided.

In addition, the method according to the present invention can be characterized in that in step b) the reaction gas is provided with a pressure selected in the range of 10⁻⁹ hPa to 10⁵ hPa, preferably selected in the range of 10⁻⁵ hPa to 10⁵ hPa. In the method according to the present invention, a wide variety of elemental materials, in particular all metals providable as a solid source material, can be used as first source materials and if applicable as one of the one or more second source material. This leads to a vast variety of selectable target oxides, wherein each of the target oxides has a reaction gas pressure and/or a reaction gas pressure range most suitable for the deposition of that specific target oxide as oxide layer. By providing the reaction gas with a pressure selected in the range of 10⁻⁹ hPa to 10⁵ hPa, preferably selected in the range from 10⁻⁵ hPa to 10⁵ hPa, for most, if not all target oxides the respective most suitable pressure and/or pressure range can be selected for the reaction gas.

The TLE system, especially the gas system of the TLE system, is preferably capable to provide the reaction gas with any pressure in this range, namely with a pressure as low as 10⁻⁹ hPa, preferably 10⁻⁵ hPa, and likewise with a pressure as high as 10⁵ hPa. Thereby the same TLE system can be used for producing an unprecedentedly wide variety of oxide layers with exceedingly high quality of the deposited target oxide.

According to another embodiment, the method according to the present invention can comprise that that before step c) a step of preparing a surface of the substrate intended for the deposition of the oxide layer is carried out. The surface condition of the substrate influences the deposition of the oxide layer. For instance, for a crystalline substrate, defects in a crystal lattice of the substrate and/or steps due to a misalignment of the surface cut to a crystal plane of the substrate and/or impurities at the surface can continue as defects in the deposited layer. By introducing a step of preparing the surface of the substrate, said surface condition of the substrate can be improved for the subsequent deposition of the target oxide as oxide layer. Providing the exceedingly high quality of the oxide layer reachable during the execution of the method according to the present invention can thereby be supported.

The method according to the present invention can be enhanced further by that the step of preparing the surface includes tempering the surface by heating the substrate with a laser beam of the TLE system, preferably by the laser beam used in step d). Heating the substrate enables the desorption of impurity atoms, the healing of defects in the bulk, and enables especially the atoms forming the surface of the substrate to migrate and to find an energetically favorable location at the surface of the substrate, and hence to find their ideal places on the surface of the substrate, in particular for a crystalline substrate within the periodic crystal lattice of the substrate. In other words, heating the substrate triggers annealing effects, especially at the surface of the substrate. A surface of the substrate more suitable for the subsequent deposition of the target oxide as oxide layer can thereby be provided.

Additionally, or alternatively, the method according to the present invention can also comprise that the step of preparing the surface includes coating the surface with one or more buffer layers. Said one or more buffer layers can help to smoothen steps on the surface of the substrate. In addition, especially for a crystalline substrate the target oxide to be deposited as oxide layer may have a different lattice structure and/or lattice constant than the substrate. Hence, at least the first atomic layer of the target oxide on the substrate has to compensate these differences. However, a buffer layer can be suitably selected such that it comprises similar, if not even identical crystal properties compared to the target oxide within the oxide layer. Hence, by adding such a suitably selected buffer layer between the substrate and the oxide layer, the compensations of the differences of the respective crystal lattices are provided within the buffer layer, and the oxide layer can be provided with its ideal crystal structure starting from the first atomic layer of the target oxide.

According to a first enhanced embodiment, the method according to the present invention can be enhanced by that the buffer layer comprises, preferably consists of, the first source material and/or an oxide of the first source material, in particular the first binary oxide.

According to an additional, or alternative, second enhanced embodiment, the method according to the present invention can be enhanced by that the buffer layer comprises, preferably consists of, one of the one or more second source materials and/or an oxide of one of the one or more second source materials, in particular one of the one or more second binary oxides.

According to an again additional, or alternative, third enhanced embodiment, the method according to the present invention can be enhanced by that the buffer layer comprises, preferably consists of, the material of the substrate.

In the first two alternative embodiments, the buffer layer is formed by evaporation and/or sublimation of a source material already present in the reaction chamber for the subsequent deposition of the target oxide as oxide layer. The need for providing additional deposition sources with additional source materials can be avoided in both alternative enhanced embodiments. Depending on the lattice structure of the target oxide, the most suitable composition of the buffer layer can be chosen based on the components already present in the TLE system: the first source material or an oxide of the first source material, or, if applicable, one of the one or more second source materials or an oxide of the one or more second source materials. For the third alternative embodiment, providing respective deposition sources providing said constituents of the material of the substrate, preferably as elemental material, might be necessary. Providing a buffer layer comprising, preferably consisting of, the substrate material provides the advantage that said buffer layer can be deposited with high quality. Defects on the surface of the substrate itself can thereby be smoothen. Also, a buffer layer comprising two or more sublayers of these materials can be implemented if suitable for the subsequent deposition of the target oxide forming the oxide layer.

Further, the method according to the present invention can be characterized in that before step c) a step of preparing the evaporation and/or sublimation is carried out, wherein the first source material and/or the one or more second source materials are heated by a laser beam, preferably the laser beam used in step c), for cleaning the first source material and/or the one or more second source material, respectively, without deposition of material onto the substrate. In step c) of the method according to the present invention, the first source material, and if applicable also the one or more second source materials, are evaporated and/or sublimated by the respective laser beams. In other words, the laser beams impinge onto the surface of the respective deposition source, and the respective source material evaporates and/or sublimates. However, especially at the beginning of the evaporation and/or sublimation process, said surface of the respective deposition source might be contaminated by impurities. By a preceding heating of the respective source material, said impurities can be eliminated, again by evaporation and/or sublimation. For avoiding a deposition of the evaporated and/or sublimated impurities onto the substrate, the substrate can be shielded and/or moved aside. Also, a removal of the substrate from the reaction chamber is possible for this preparation step, preferably via airlocks. In summary, by said preparing step an evaporation and/or sublimation of the respective source materials with high purity can be provided from the beginning of the execution of step c) of the method according to the present invention.

According to a second aspect of the invention, the object is satisfied by a TLE system constructed for carrying out the method according to the first aspect of the present invention. The TLE system according to the second aspect of the present invention comprises:
The reaction chamber,
One or more laser sources for providing laser beams for heating the substrate and for evaporating and/or sublimating the one or more source materials,
Coupling means for coupling the one or more laser beams into the reaction chamber,
Arrangement means for arranging the substrate and the one or more deposition sources providing the one or more source materials in the reaction chamber, and
The gas system for providing the reaction gas within the reaction chamber.

The TLE system according to the second aspect of the present invention is constructed for carrying out the method according to the first aspect of the present invention. Hence, all features and advantages described in detail with respect to the method according to the first aspect of the present invention can also be provided by the TLE system according to the second aspect of the present invention.

As already mentioned, the TLE system, especially the respective laser source and the laser beam provided by said laser source, is preferably capable to heat the substrate to any temperature in this range, namely to a temperature as low as 250° K and likewise to a temperature as high as 4500° K. Thereby the same TLE system can be used for producing an unprecedentedly wide variety of oxide layers with exceedingly high quality.

Additionally, or alternatively, and as also already mentioned, the TLE system, especially the gas system of the TLE system, is preferably capable to provide the reaction gas with any pressure in this range, namely with a pressure as low as 10⁻⁹ hPa, preferably 10⁻⁵ hPa and likewise with a pressure as high as 10⁵ hPa. Thereby the same TLE system can be used for producing an unprecedentedly wide variety of oxide layers with exceedingly high quality of the deposited target oxide.

A single laser source can be used for evaporating and/or sublimating the respective source materials, wherein for each of the source materials a separate laser beam is provided. Alternatively, also separate laser sources, each providing a laser beam specifically selected for a respective source material, can be implemented.

The reaction chamber can be equipped with airlocks for an access into the reaction chamber without losing and/or contaminating the present atmosphere within the reaction chamber. Said airlocks can be used for instance for installing and/or removing the substrate and/or one or more of the used deposition sources.

The invention will be explained in detail in the following by means of embodiments and with reference to the drawings. In particular, in the figures are shown:

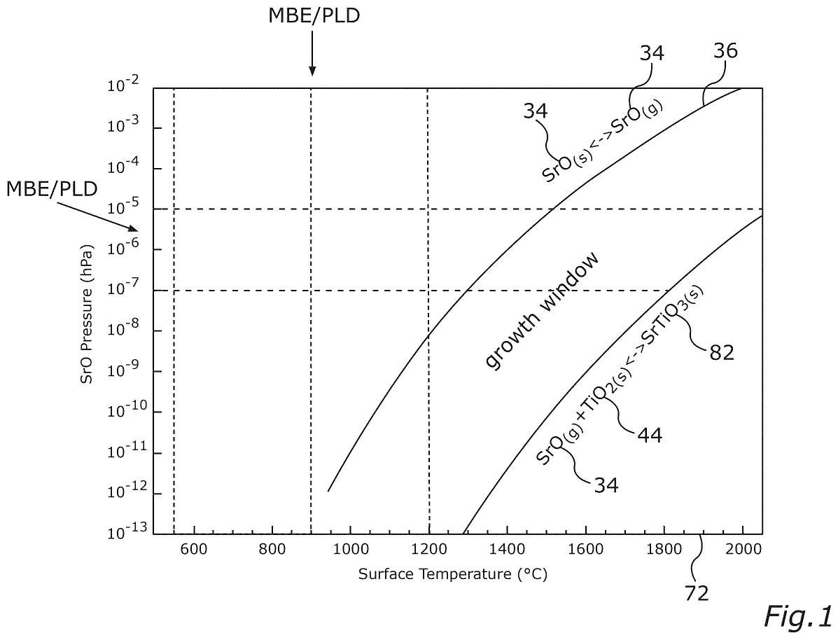

FIG. 1A phase diagram for SrTiO₃,

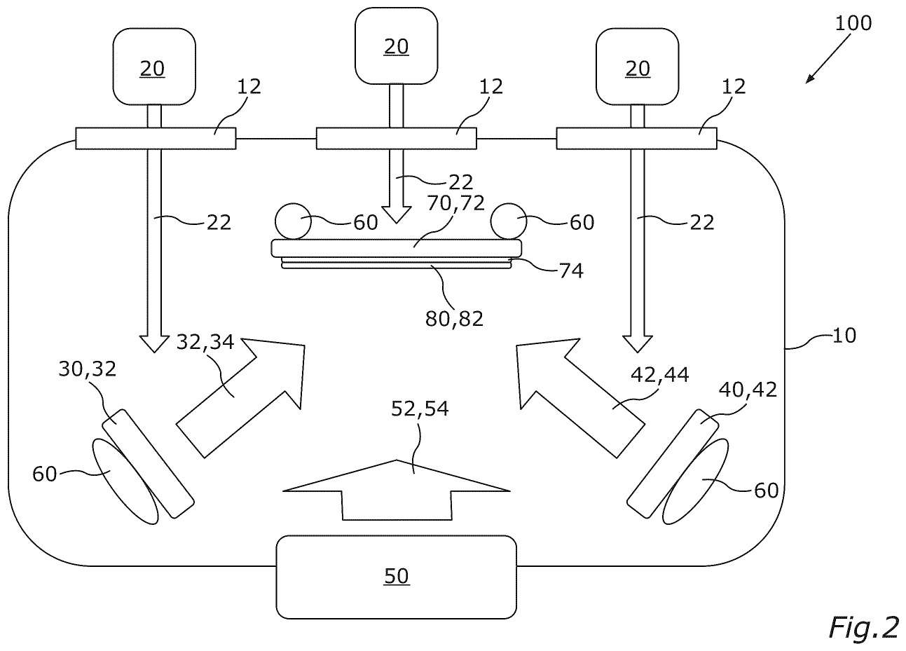

FIG. 2A schematic view of a TLE system according to the present invention,

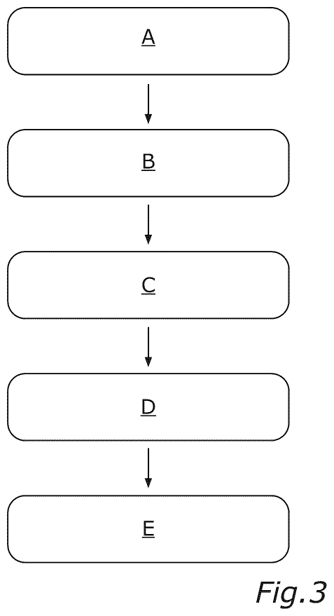

FIG. 3A schematic view of a method according to the present invention,

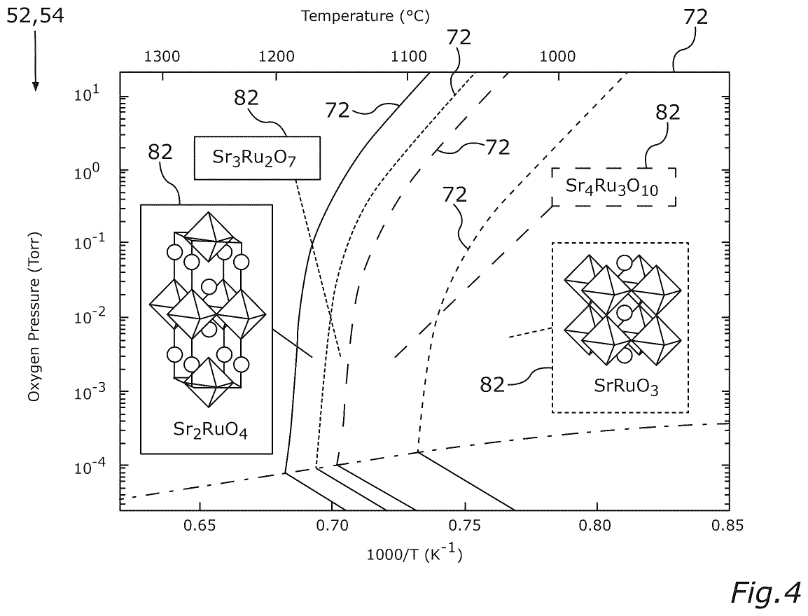

FIG. 4A phase diagram for Sr—Ru—O Ruddlesden Popper materials,

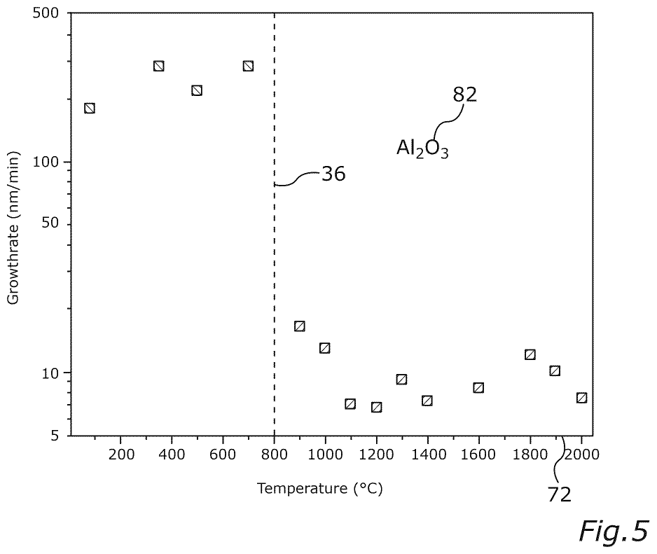

FIG. 5A growth rate of Al₂O₃ vs. deposition temperature, and

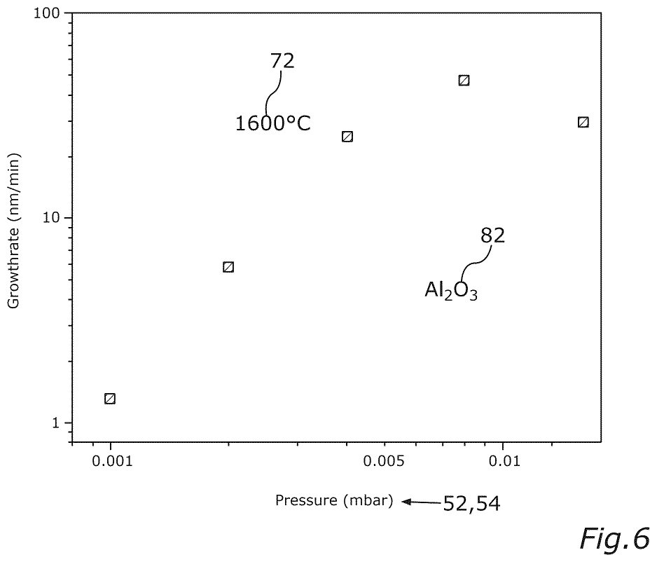

FIG. 6A growth rate of Al₂O₃ vs. pressure of the reaction gas.

In FIG. 1 a calculated phase diagram is depicted for a possible target oxide 82, namely SrTiO₃, as it is known in the state of the art. In the diagram, the pressure, and hence the flux, of SrO as first binary oxide 34 of a first source material 32 (not explicitly depicted) is shown versus possible deposition temperatures 72 of a substrate 70, on which ideally the target oxide 82 should be deposited as oxide layer 80 (see FIG. 2).

The upper line marked as desorption temperature 36 denotes, depending on the pressure of the first binary oxide 34, the boundary temperature, beyond which, to the right and below this line, the first binary oxide 34 will desorb from the surface of the substrate 70. The second, unmarked line denotes the boundary temperature beyond which, to the right and below this line, the substrate 70 and/or the target oxide 82 on the substrate 70, and hence the oxide layer 80, is no longer stable enough for effective growth and phase separates into the more stable TiO₂ and gaseous SrO. In between these lines, in the area denoted by “growth window”, an adsorption-controlled growth of the target oxide 82 SrTiO₃ is possible, as the first binary oxide 34 SrO desorbs, preferably completely desorbs, and hence the flux density or local pressure of the second binary oxide 44 TiO limits and hence defines the growth rate of the target oxide 82 SrTiO₃.

However, also depicted in FIG. 1 are areas in said diagram space, which can be reached with MBE and PLD processes of the state of the art. It is clearly visible, that with said deposition processes known in the state of the art, a deposition of SrTiO₃ as target oxide 82 in the adsorption-limited growth mode is not possible, since the intersection of the ranges of accessible temperatures of the substrate 70 (550-900, in special cases up to 1200° C.) and SrO pressures (10⁻⁷ to 10⁻⁵ hPa) for technologically useful growth rates of 0.01 to 1 formula unit layers per second, do not lie within the growth window.

However, thermal laser epitaxy is a deposition process, which intrinsically does not comprise the limitations concerning possible deposition temperatures 72 of the substrate 70 present in MBE, but can simultaneously provide fluxes of almost arbitrary source materials at purities significantly higher than PLD. In fact, the purity of the provided fluxes of source materials are at least similar, mostly even better than achievable in MBE processes.

Hence, according to the present invention an accordingly constructed TLE system 100, depicted in FIG. 2, is used for execution of a method according to the present invention as depicted in FIG. 3, for providing a controlled deposition of an oxide layer 80 of a target oxide 82 on a substrate 70. In the following, the TLE system 100 and the method according to the present invention, respectively, are described together.

As already mentioned, the method according to the present invention is carried out in an accordingly constructed TLE system 100. The main part of said TLE system 100 is a reaction chamber 10, in which the deposition of the oxide layer 80 on the substrate 70 takes place. Further parts of the TLE system 100 are one or more, as exemplarily depicted three, laser sources 20 for providing laser beams 22, and a gas system 50, fluidly connected to the interior of the reaction chamber 10.

The laser beams 22 are used for both, evaporating and/or sublimating source material 32, 42, and for heating the substrate 70, respectively. For guiding said laser beams 22 to their respective destination within the reaction chamber 10, suitable coupling means 12 are provided. Preferably, the laser beams 22 are continuous or at least comprise a pulse intensity below the plasma generation threshold. In the latter case, the pulse length preferably can be selected equal to or larger than 1 μs, in particular larger than 1 ms, preferably larger than 1 s.

The gas system 50 is at least capable of filling the reaction chamber 10 with a reaction gas 52 comprising, preferably consisting of, one or more oxidizing agents 54 such as for instance molecular oxygen (O₂), ozone (O₃), plasma-activated oxygen (O₂*), ionized oxygen (O⁻), atomic oxygen (O), or combinations of the foregoing. The reaction gas 52 can be provided as directed flow towards the substrate 70. Preferably, the reaction gas 52 consists of a single oxidizing agent 54. The one or more oxidizing agents 54 are the sources of the oxygen atoms needed for the formation of the target oxide 82, as will be described in the following. The gas system 50 can provide the reaction gas 52 with a wide variety of pressures, preferably pressures selected in the range of 10⁻⁵ hPa to 10⁵ hPa. In most of the embodiments, the gas system 50 not only provides the reaction gas 52, but is also capable of evacuating the reaction chamber 10.

Further in the reaction chamber 10, the substrate 70 to be coated with an oxide layer 80 is provided, held in place by arrangement means 60. The oxide layer 80 is formed by depositing a target oxide 82, which comprises a defined stoichiometry and is formed from one or more evaporated and/or sublimated source materials 32, 42 and by oxygen originating from the gaseous oxidizing agent 54. As it will be described in the following, one of the laser beams 22 is used for heating the substrate 70 to a deposition temperature 72 suitably selected for the intended deposition of the oxide layer 80.

The one or more components of the target oxide 82 different to oxygen are provided by evaporating and/or sublimating one or more source materials 32, 42. In the depicted embodiment of the TLE system 100, a first deposition source 30 containing an elemental material, preferably an elemental metal, as first source material 32 and a second deposition source 40 containing an elemental material, preferably an elemental metal, as second source material 42 are provided, in particular held in place within the reaction chamber 10 by accordingly constructed and provided arrangement means 60. Each of the source materials 32, 42 is evaporated and/or sublimated by a respective laser beam 22. As the source materials 32, 42 are provided as elemental materials, the evaporated and/or sublimated source materials 32,42 can be extremely pure. Only reactions with the one or more oxidizing agents 54 of the reaction gas 52 can lead to a formation of a first binary oxide 34 and a second binary oxide 44, respectively.

The source materials 32, 42 usable in the TLE system 100 according to the present invention and for the method according to the present invention are variable. In particular, all elemental materials can be used as source material 32, 42, in particular Li, Na, K, Ca, Sr, Y, Ag, Ba, La, Ce, Pr, Nd, Sm, Eu, Gd, Tb, Dy, Ho, Er, Tm, Yb, Lu, Pb, Bi, Al, Sc, Ti, V, Cr, Mn, Fe, Co, Ni, Ga, Zr, Mo, Ru, Rh, Pd, In, Sn, Sb, Be, B, Mg, Si, Cu, Zn, Ge, Se, Cd, Te, Cs, Re, Pt, Au, Hg, Tl, Th, U, Np, Pu, Am, Tc, Os, Rb, and As.

In the following, the method according to the present invention is described in detail. Please note that step a) A is already finished in the TLE system 100 depicted in FIG. 2. Further please note that steps b) B, c) C, d) D, and e) E can be carried out simultaneously.

In a first step a) A, the substrate 70 and all used deposition sources 30, 40 are arranged in the reaction chamber 10. Afterwards, the reaction chamber 10 is closed and sealed with respect to the ambient environment, and preferably evacuated by the gas system 50.

This allows in the next step b) B to fill the reaction chamber 10 with the reaction gas 50. Please note that said filling in step b) B can be preferably carried out continuously additionally also throughout all following steps c) C, d) D, and e) E of the method according to the present invention.

To ensure continued purity of the reaction gas 52, filling of the reaction gas 52, preferably from one side of the TLE system 100, even more preferably by a nozzle directed to the front of the substrate 70, and pumping of the reaction gas 52 from the other side of the TLE system 100, may be performed simultaneously by different parts of the gas system 50 (not depicted).

As further preparation of the subsequent deposition of the oxide layer 80 on the substrate 70, the surface of the substrate 70 can be prepared, for instance by heating the substrate to perform annealing processes. Alternatively, or additionally, as depicted in FIG. 2 also a buffer layer 74 can be deposited onto the surface of the substrate 70, for instance consisting of elements already present in the reaction chamber 10 such as the first source material 32, the first binary oxide 34, the second source material 42 and/or the second binary oxide 44.

Further preparation steps may include pre-heating the source materials 32, 42 for cleaning purposes, wherein a deposition of already evaporated and/or sublimated material on the substrate is avoided.

In the following step c) C of the method according to the present invention, the actual evaporation and/or sublimation of the source materials 32, 42 is provided. For this, the intensity of the respective laser beams 22 are selected such that they are below a plasma threshold of the respective source material 32, 42. Thereby, a strictly thermal evaporation and/or sublimation can be provided. The flux of evaporated and/or sublimated source material 32, 42, or existing of an accordingly formed binary oxide 34, 44, is directed towards the substrate 70 for the subsequent coating of the substrate 70.

In the following step d) D, the substrate 70 is heated by an accordingly provided laser beam 22. In this crucial step, the substrate 70 is in particular heated to a deposition temperature 72, which is equal or higher to a desorption temperature 36 (see FIG. 5) of the first source material 32 or the first binary oxide 34, respectively. Depending on the respective first source material 32, and especially of the respective first binary oxide 34, the deposition temperature 72 can be preferably selected between 250° K and 4500° K.

Thereby the first source material 32 or the first binary oxide 34 desorbs from the substrate 70. The deposition temperature 72 can be preferably selected such that more than 40%, in particular more than 70%, preferably more than 99.9%, of the incoming flux of the first source material 32 and if present of the first binary oxide 34 desorbs from the substrate 70. This ensures that the deposition of the target oxide 82 solely depends on the component or components additionally needed to form the target oxide 82. In the case of a binary oxide as target oxide 82, this is the available amount of oxygen at the substrate (see FIG. 6), in the case of a ternary or multernary oxide as target oxide 82, this is one of the one or more additional second source materials 42, or the respective second binary oxides 44 of said second source material 42.

In summary, said heating of the substrate 70 in step d) allows an adsorption-controlled deposition of the target oxide 82 and hence of the oxide layer 80 in step e) of the method according to the present invention. In other words, the amount of compounds needed in addition to the first source material 32 and/or the first binary oxide 34, namely predominantly the one or more second source material 42 and/or the one or more second binary oxide 44, in addition sometimes also the amount of available oxygen provided by the one or more oxidizing agents 54, solely defines and hence controls the formation rate of the target oxide 82 and hence the growth rate of the oxide layer 80. For said control, the one or more second source material 42 and/or the respective one or more second binary oxide 44 can be provided with an intermittent and/or constant and/or variable flux, for accordingly altering the growth rate of the oxide layer 80.

In particular, due to the desorption of the first source material 32 and/or, if present, of the first binary oxide 34 from the substrate, the formation of the target oxide 82 and the deposition of the oxide layer 80 on the substrate 70 can be provided with an exceedingly high quality. This is due to the physical effect that a deposition of the target oxide 82 predominantly only takes place, if the formed compound, namely the target oxide 82, possess the required suitable thermodynamic properties, which dominantly depend on the substrate temperature, namely the deposition temperature 72. Thereby the deposited compound, namely the target oxide 82, can be actively selected and hence the quality of the deposited oxide layer 80, in particular concerning high purity and low defect density, can be maximized. Defect densities concerning nevertheless deposited elements of the first source material 32 and/or the first binary oxide 34 as low as 1 in 10⁴, in particular less than 1 in 10⁷, preferably less than 1 in 10¹⁰, can be achieved.

In FIG. 4, another advantage of the method according to the present invention is demonstrated. By accordingly controlling the variables of the deposition process, the actual target oxide 82 can be specifically selected. As depicted, even target oxides 82 with different stoichiometries of the same constituents can be provided. In particular, said selection can be provided very rapidly, within less than 5 seconds. Thereby an oxide layer 80 comprising different sub-layers of the same constituents but different structures can be provided.

FIG. 4 actually depicts the thermodynamic phase diagram for different Sr—Ru—O Ruddlesden-Popper materials. Such Ruddlesden-Popper materials, as well as oxides with perovskite or perovskite-related structures, can be deposited with exceedingly high quality by implementing the method according to the present invention.

The phase diagram shows the dependency of the respective deposition temperature 72 most suitable for selecting the respective structure as target oxide 82, on the oxygen pressure provided by the reaction gas 52. It is clearly visible that by accordingly controlling said pressure and the heating of the substrate 70, a specific selection of the target oxide 82 for the deposition of the oxide layer 80 can be made.

It was found experimentally that a deposition temperature of 1000° C. to 1300° C. and a pressure of 10⁻⁴ to 10⁻² hPa (□ Torr) of oxygen as oxidizing agent 54 leads to a deposition of high-quality epitaxial crystalline films of Sr₂RuO₄ as target oxide 82 of the oxide layer 80.

Likewise, it was found that a deposition temperature of 600° C. to 1000° C. and a pressure of 5×10⁻³ to 2×10⁻² hPa of oxygen as oxidizing agent 54 leads to a deposition of high-quality epitaxial crystalline films of SrRuO₃ as target oxide 82 of the oxide layer 80.

In both cases, the provided fluxes of Ru as first source material 32 (5×10¹² and 3×10¹⁴ atoms/s*cm²) and Sr as second source material 42 (1×10¹³ and 1×10¹⁵ atoms/s*cm²) were the same.

In FIG. 5, 6, a proof of principle for the execution of the method for a binary oxide, namely Al₂O₃, as target oxide 82 is depicted. In the following, both FIG. 5, 6 are described together. In summary the capability of TLE to grow epitaxial adsorption-controlled binaries is demonstrated by the depicted adsorption-controlled growth of c-plane sapphire (Al₂O₃). Please note that Al₂O₃ is predicted to have one of the highest deposition temperatures 72 to be grown in adsorption-control (in vacuum environment 1650° K. Further, it is of high scientific and industrial relevance due to its high bandgap (9 eV), high dielectric constant (9), high thermal conductivity (46 W/Km), and high thermal stability. It is used for instance as a high-k gate oxide, for numerous optical applications, and investigated for high power electronics.

The high thermal stability goes along with the aforementioned high deposition temperature 72 required to induce volatility. FIG. 5 shows the growth rate at a fixed elemental flux as a function of the substrate temperature. A drastic drop of the growth rate is observed at 900° C., which is the desorption temperature 36 of Al₂O₃ at the provided pressure of the reaction gas 52 (see FIG. 2) of 0.001 hPa. At this temperature of 900° C., the actual desorbing species are suboxides of Al₂O₃ and pure Al, which is the first source material 32 (see FIG. 2).

The growth rate in the adsorption-controlled regime, which can be selected by heating the substrate 70 to a temperature well beyond the desorption temperature 36 depicted in FIG. 5, is thus determined by the supplied flux of reaction gas 52 or oxidizing agents 54, respectively, which enables the oxidation into the less volatile Al₂O₃. This is illustrated in FIG. 6 which shows the growth rate as a function of the pressure of the reaction gas 52, in this case O₂, at a fixed flux of the first source material 32 (pure Al) and with the substrate 70 heated to a deposition temperature 72 of 1600° C.

As is clearly visible, the growth rate increases with an increased supply of the oxidizing agent 54 in this case molecular oxygen—until the mean free path limits the growth rate at high pressures. This demonstrates on the one hand the ability to grow Al₂O₃ in an adsorption-controlled way—a binary previously not demonstrated to grow adsorption-controlled. Further it also shows that the rate of formation of the target oxide 82, and hence of the growth rate of the oxide layer 80, can also be controlled by actively controlling the filling of the reaction chamber 10 with reaction gas 52.

List of references

| | |
|---|---|
| 10 | Reaction chamber |
| 12 | Coupling means |
| 20 | Laser source |
| 22 | Laser beam |
| 30 | First deposition source |
| 32 | First source material |
| 34 | First binary oxide |
| 36 | Desorption temperature |
| 40 | Second deposition source |
| 42 | Second source material |
| 44 | Second binary oxide |
| 50 | Gas system |
| 52 | Reaction gas |
| 54 | Oxidizing agent |
| 60 | Arrangement means |
| 70 | Substrate |
| 72 | Deposition temperature |
| 74 | Buffer layer |
| 80 | Oxide layer |
| 82 | Target oxide |
| 100 | TLE system |
| A | step a) |
| B | step b) |
| C | step c) |
| D | step d) |
| E | Step e) |

1-31. (canceled)

32. Method for the controlled deposition of an oxide layer of an target oxide on a substrate in a thermal laser epitaxy system, the target oxide comprising a defined stoichiometry and being formed from one or more evaporated and/or sublimated source materials and oxygen originating from a gaseous oxidizing agent, the TLE system further comprising a reaction chamber and one or more laser sources for providing laser beams within the reaction chamber,
comprising the steps of:
a) providing the substrate and a first deposition source in the reaction chamber, wherein the first deposition source contains an elemental material as first source material,
b) filling the reaction chamber with a reaction gas comprising one or more oxidizing agents provided by a gas system of the TLE system,
c) evaporating and/or sublimating the first source material by impinging a laser beam of the TLE system on the first source material with an intensity below a plasma generation threshold of the first source material, for providing a flux of evaporated and/or sublimated first source material and/or of a first binary oxide formed from the first source material with the oxidizing agent, wherein the flux is directed towards the substrate,
d) heating the substrate to a deposition temperature by a laser beam of the TLE system, wherein the deposition temperature of the substrate is equal or higher to a desorption temperature such that the first deposition source and/or the first binary oxide desorb at least partly from the substrate,
e) forming the target oxide by combining the one or more evaporated and/or sublimated source materials and oxygen originating from the one or more oxidizing agents and depositing the target oxide as oxide layer onto the substrate, wherein the formation of the target oxide and the deposition of the oxide layer on the substrate is controlled by controlling the filling of the reaction chamber with the reaction gas in step b) and/or by controlling the rate of the evaporated and/or sublimated first source material at the substrate in step c) and/or by controlling the deposition temperature in step d).

33. Method according to claim 32,
wherein in step d) the deposition temperature is selected such that more than 40% of the incoming flux of the first source material desorbs from the substrate, and that in step e) the adsorbed part of the first source material combined with oxygen originating from the one or more oxidizing agents and/or the first binary oxide form the target oxide for the deposition of the oxide layer.

34. Method according to claim 32,
wherein in step a) one or more second deposition sources are provided in the reaction chamber, wherein each second deposition source contains an elemental material as second source material,
further that step c) includes evaporating and/or sublimating one or more second source materials by impinging a laser beam of the TLE system on the one or more second source materials with an intensity below a plasma generation threshold of the respective second source material, for providing a flux of evaporated and/or sublimated one or more second source materials and/or of one or more second binary oxides formed from one of the one or more second source materials with the oxidizing agent directed towards the substrate, wherein in step e) the first deposition source and/or the first binary oxide combined with the one or more second deposition sources and/or the one or more second binary oxides, if necessary additionally combined with oxygen originating from the one or more oxidizing agents, form the target oxide for the deposition of the oxide layer, and that in step d) the deposition temperature of the substrate is equal or higher to a temperature such that the first deposition source and/or the first binary oxide desorb if they are not used for forming the target oxide.

35. Method according to claim 34,
wherein the deposition temperature in step d) is selected high enough that the amount of first deposition source and/or first binary oxide nevertheless deposited onto the substrate is less than 1 in 10⁴ compared to elements of the target oxide.

36. Method according to claim 34,
wherein in step c) the one or more evaporated and/or sublimated second source materials and/or the one or more second binary oxide is provided with an intermittent and/or constant and/or variable flux by accordingly controlling the laser beam used for evaporating and/or sublimating the one or more second source materials.

37. Method according to claim 34,
wherein the target oxide formed in step e) comprises a perovskite structure and/or perovskite-related structure and/or Ruddlesden-Popper structure.

38. Method according to claim 32,
wherein in step d) the deposition temperature is selected such that the first source material and/or the first binary oxide and/or the one or more second source materials and/or the one or more second binary oxides are enabled to migrate along a surface of the substrate.

39. Method according to claim 32,
wherein in step d) the deposition temperature is provided between 250° K and 4500° K.

40. Method according to claim 32,
wherein in step d) the deposition temperature is selected with respect to the first binary oxide.

41. Method according to claim 40,
wherein the deposition temperature is selected with respect to the first binary oxide equal or higher as listed below:

| | | | | | | | | |
|---|---|---|---|---|---|---|---|---|
| Li₂O | 1075° | K | Al₂O₃ | 1650° | K | BeO | 1625° | K |
| Na₂O | 800° | K | Sc₂O₃ | 1750° | K | B₂O₃ | 1000° | K |
| K₂O | 680° | K | TiO₂ | 1750° | K | MgO | 1300° | K |
| CaO | 1450° | K | V₂O₅ | 780° | K | SiO₂ | 1350° | K |
| SrO | 1575° | K | Cr₂O₃ | 1350° | K | CuO | 950° | K |
| Y₂O₂ | 1750° | K | MnO | 1300° | K | ZnO | 900° | K |
| Ag₂O | 850° | K | FeO | 1300° | K | GeO | 1050° | K |
| BaO | 1100° | K | CoO | 1250° | K | SeO₂ | 300° | K |
| La₂O₂ | 1650° | K | NiO | 1200° | K | CdO | 750° | K |
| Ce₂O₃ | 1700° | K | Ga₂O₃ | 1275° | K | TeO₂ | 700° | K |
| Pr₂O₃ | 1700° | K | ZrO₂ | 1750° | K | CsO₂ | 500° | K |
| Nd₂O₃ | 1700° | K | MoO₃ | 750° | K | Re₂O₇ | 300° | K |
| Sm₂O₃ | 1750° | K | RuO₂ | 950° | K | PtO | 1100° | K |
| Eu₂O₃ | 1600° | K | RhO | 1100° | K | Au₂O₃ | 700° | K |
| Gd₂O₃ | 1750° | K | PdO | 900° | K | HgO | 300° | K |
| Tb₂O₃ | 1850° | K | In₂O₃ | 1100° | K | Tl₂O | 700° | K |
| Dy₂O₃ | 1900° | K | SnO₂ | 1000° | K | ThO₂ | 1750° | K |
| Ho₂O₃ | 1850° | K | SbO₂ | 750° | K | UO₃ | 500° | K |
| Er₂O₃ | 1775° | K | Lu₂O₃ | 1950° | K | NpO₂ | 2250° | K |
| Tm₂O₃ | 2000° | K | PbO | 800° | K | PuO₂ | 1500° | K |
| Yb₂O₃ | 1750° | K | Bi₂O₃ | 850° | K | Am₂O₃ | 1875° | K |

42. Method according to claim 32,
wherein in step c) a continuous laser beam or a laser beam with an intensity below the plasma generation threshold, is used.

43. Method according to claim 32,
wherein in step b) a pressure and/or a composition of the reaction gas is varied by accordingly controlling the gas system of the TLE system for actively changing the stoichiometry of the formed target oxide without changing the constituents.

44. Method according to claim 32,
wherein in step c) the provided flux of evaporated and/or sublimated first source material and/or of a first binary oxide is varied by accordingly controlling the laser beam of the TLE system used in step c) for actively changing the stoichiometry of the formed target oxide without changing the constituents.

45. Method according to claim 32,
wherein in step d) the deposition temperature of the substrate is varied by accordingly controlling the laser beam of the TLE system for actively changing the stoichiometry of the formed target oxide without changing the constituents.

46. Method according to claim 43,
wherein the variation of the reaction gas and/or the variation of the provided flux of evaporated and/or sublimated first source material and/or of a first binary oxide and/or the variation of the deposition temperature are provided before and/or during and/or after an iteration of step c).

47. Method according to claim 43,
wherein the oxide layer deposited in step e) comprises two or more subsequent sub-layers formed by target oxides with the same constituents but different stoichiometry.

48. Method according to claim 32,
wherein the first source material and/or the one or more second source material is an elemental metal.

49. Method according to claim 32,
wherein the first source material and/or the one or more second source material is selected from a group of materials comprising the members of: Li, Na, K, Ca, Sr, Y, Ag, Ba, La, Ce, Pr, Nd, Sm, Eu, Gd, Tb, Dy, Ho, Er, Tm, Yb, Lu, Pb, Bi, Al, Sc, Ti, V, Cr, Mn, Fe, Co, Ni, Ga, Zr, Mo, Ru, Rh, Pd, In, Sn, Sb, Be, B, Mg, Si, Cu, Zn, Ge, Se, Cd, Te, Cs, Re, Pt, Au, Hg, Tl, Th, U, Np, Pu, Am, Tc, Os, Rb, As.

50. Method according to claim 32,
wherein step b) is carried out continuously during the execution of step c) and/or step d) and/or step e).

51. Method according to claim 32,
wherein in step b) the filling of the reaction chamber includes providing a directed flow of reaction gas towards the substrate.

52. Method according to claim 32,
wherein the reaction gas consists of a single oxidizing agent.

53. Method according to claim 32,
wherein the one or more oxidizing agents are selected from the group of members consisting of molecular oxygen, ozone, plasma-activated oxygen, ionized oxygen, atomic oxygen, and combinations of the foregoing.

54. Method according to claim 32,
wherein in step b) the reaction gas is provided with a pressure selected in the range of 10⁻⁹ hPa to 10⁵ hPa.

55. Method according to claim 32,
wherein before step c) a step of preparing a surface of the substrate intended for the deposition of the oxide layer is carried out.

56. Method according to claim 55,
wherein the step of preparing the surface includes tempering the surface by heating the substrate with a laser beam of the TLE system.

57. Method according to claim 55,
wherein the step of preparing the surface includes coating the surface with one or more buffer layers.

58. Method according to claim 57,
wherein the buffer layer comprises the first source material and/or an oxide of the first source material.

59. Method according to claim 57,
wherein the buffer layer comprises one of the one or more second source materials and/or an oxide of one of the one or more second source materials.

60. Method according to claim 57,
wherein the buffer layer comprises the material of the substrate.

61. Method according to claim 32,
wherein before step c) a step of preparing the evaporation and/or sublimation is carried out, wherein the first source material and/or the one or more second source materials are heated by a laser beam for cleaning the first source material and/or the one or more second source material, respectively, without deposition of material onto the substrate.

62. TLE system constructed for carrying out the method according to claim 32, comprising
The reaction chamber,
One or more laser sources for providing laser beams for heating the substrate and for evaporating and/or sublimating the one or more source materials,
Coupling means for coupling the one or more laser beams into the reaction chamber,
Arrangement means for arranging the substrate and the one or more deposition sources providing the one or more source materials in the reaction chamber, and
The gas system for providing the reaction gas within the reaction chamber.
